(19) United States
(12) Patent Application Publication
(10) Pub. No.: US 2026/0018476 A1
(43) Pub. Date: Jan. 15, 2026

(54) Semiconductor Device and Method of Forming Heat Spreader with Surface Plasma Treatment for FCBGA-H Package

(71) Applicant: STATS ChipPAC Pte. Ltd., Singapore (SG)

(72) Inventors: JongChan Park, Incheon (KR); TaeKeun Lee, Incheon (KR)

(73) Assignee: STATS ChipPAC Pte. Ltd., Singapore (SG)

(21) Appl. No.: 18/766,732

(22) Filed: Jul. 9, 2024

(51) Int. Cl. H01L 23/31; H01L 21/48; H01L 23/00; H01L 23/29; H01L 23/498

(52) U.S. Cl. CPC H01L 23/3121; H01L 21/4875; H01L 23/291; H01L 23/49827; H01L 24/13; H01L 24/16; H01L 2224/13023; H01L 2224/16227

(57) ABSTRACT

A semiconductor device has a substrate and an electrical component disposed over the substrate. A heat spreader with a plasma-enhanced surface is disposed over the electrical component. A TIM is disposed between the electrical component and plasma-enhanced surface of the heat spreader. The TIM can be deposited on the electrical component or plasma-enhanced surface. The plasma-enhanced surface contains argon ions and oxygen ions. The heat spreader is disposed in a reaction chamber. Reactant gases, such as argon and oxygen, are introduced into the reaction chamber. An electric field is formed within the reaction chamber to ionize the argon and oxygen and form the plasma-enhanced surface. The plasma-enhanced surface has properties of roughness and tacky-ness or adhesive property by nature of the surface exhibiting a chemical bonding group. An underfill material is deposited between the electrical component and substrate. The electrical component can be a flipchip type semiconductor die.

### FIELD OF THE INVENTION

The present invention relates in general to semiconductor devices and, more particularly, to a semiconductor device and method of forming a heat spreader with surface plasma treatment for fcBGA-H package.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices are susceptible to heat from operation of the semiconductor die. Some semiconductor die, such as a microprocessor, operate at a high clock frequency and generate heat from rapid transistor switching. Other semiconductor devices, such as a power MOSFET, generate heat by conducting significant current. The high output power and associated heat can be attributed to multifunction and high performance operation.

The semiconductor die is typically mounted to a substrate and a heat spreader or heat sink is mounted to the semiconductor die and an area of the substrate around the semiconductor die. In one example, flipchip ball grid array (fcBGA) packages commonly use a heat spreader (fcBGA-H) to manage the heat for stable and long-term use of the device. The heat spreader can be made of nickel-plated copper. The surface of nickel-plated copper is smooth. A portion of the heat spreader thermally contacts a thermal interface material (TIM) deposited on a top surface of the semiconductor die and another portion of the heat sink mechanically and thermally contacts the substrate. TIM can be made of silicon-based epoxy with thermal conducting fillers. The TIM dissipates heat by effectively increasing the contact area between the semiconductor die and heat spreader.

The semiconductor die and TIM are homogeneous as both contain silicon. However, the heat spreader and TIM are heterogeneous as each contains a different material. The adhesion property for a heterogeneous interface is less effective than the adhesion of a homogeneous interface. A need exists for better adhesion and bond-ability between the heat spreader and TIM.

### BRIEF DESCRIPTION OF THE DRAWINGS

FIGS. 1a-1c illustrate a semiconductor wafer with a plurality of semiconductor die separated by a saw street;

FIGS. 2a-2v illustrate a process of forming a fcBGA-H package with a plasma-enhanced surface on the head spreader to interface with the TIM;

FIGS. 3a-3b illustrate formation of the plasma-enhanced surface on the heat spreader; and

FIG. 4 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

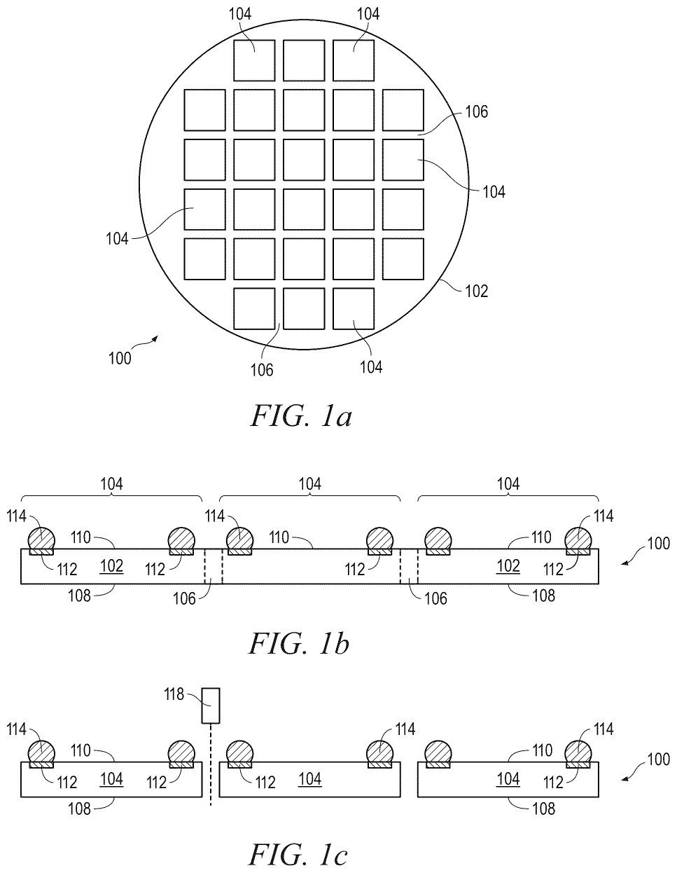

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular or any other geometric shape.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. In one embodiment, semiconductor die 104 is a flipchip type semiconductor die. The individual semiconductor die 104 can be inspected and electrically tested for identification of known good die or unit (KGD/KGU) post singulation.

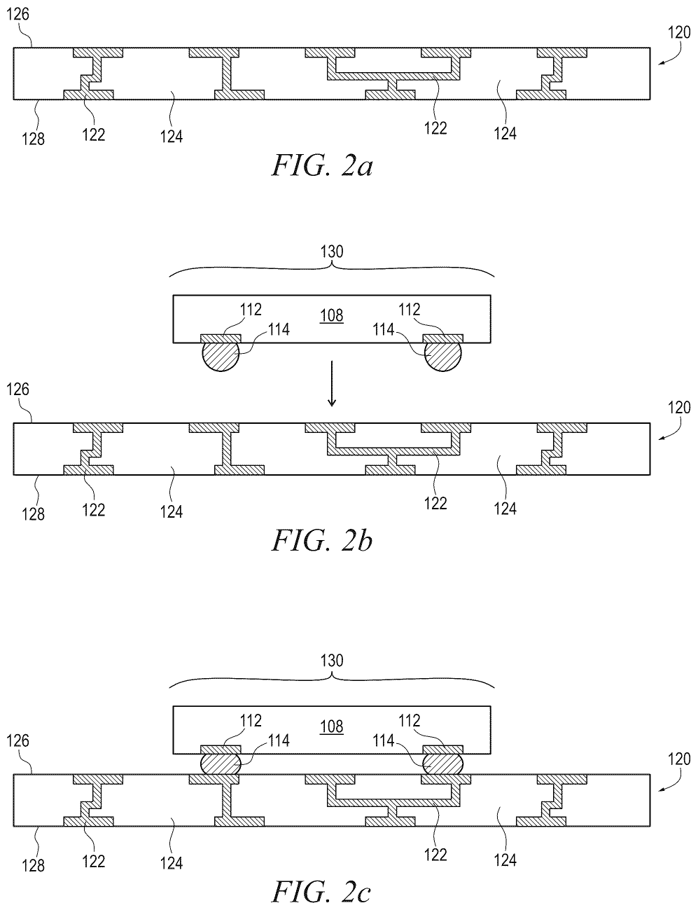

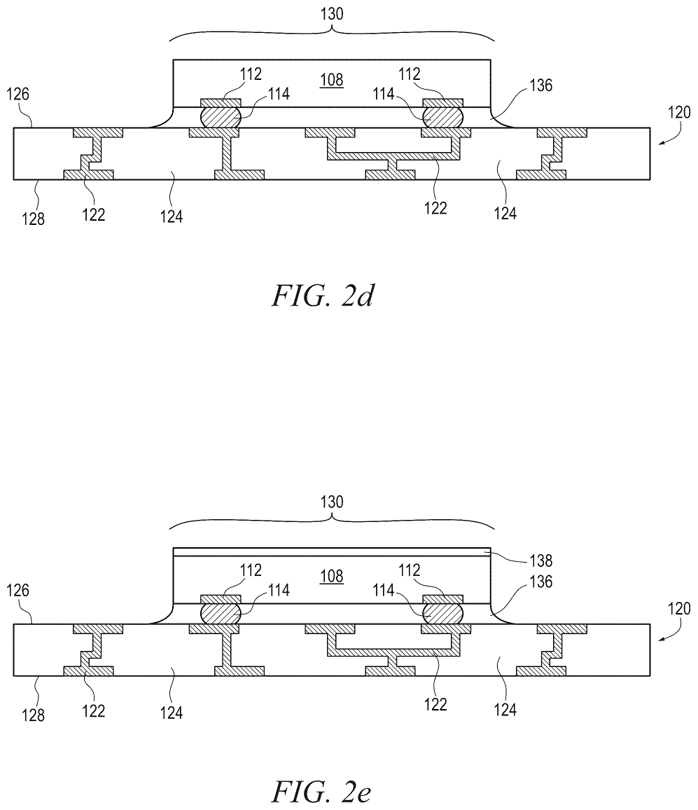

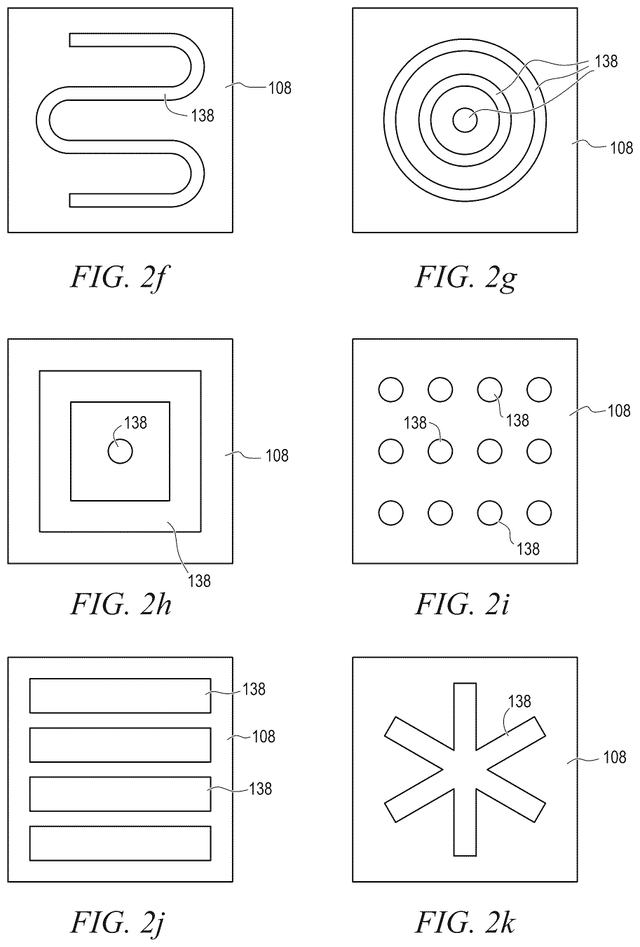

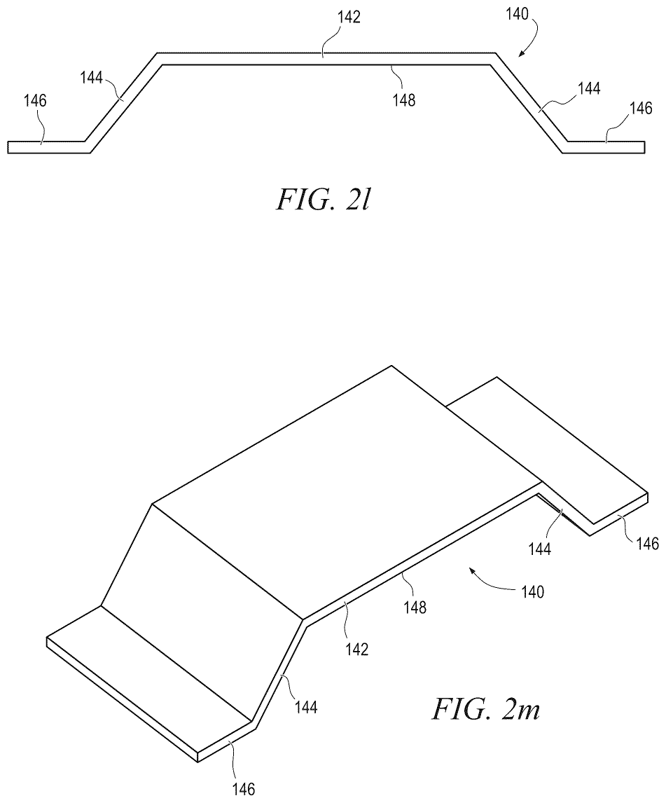

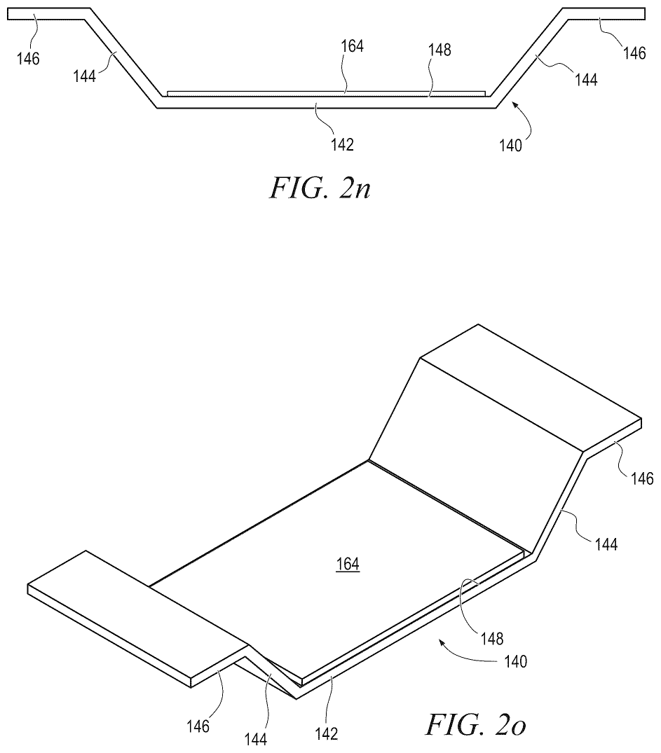

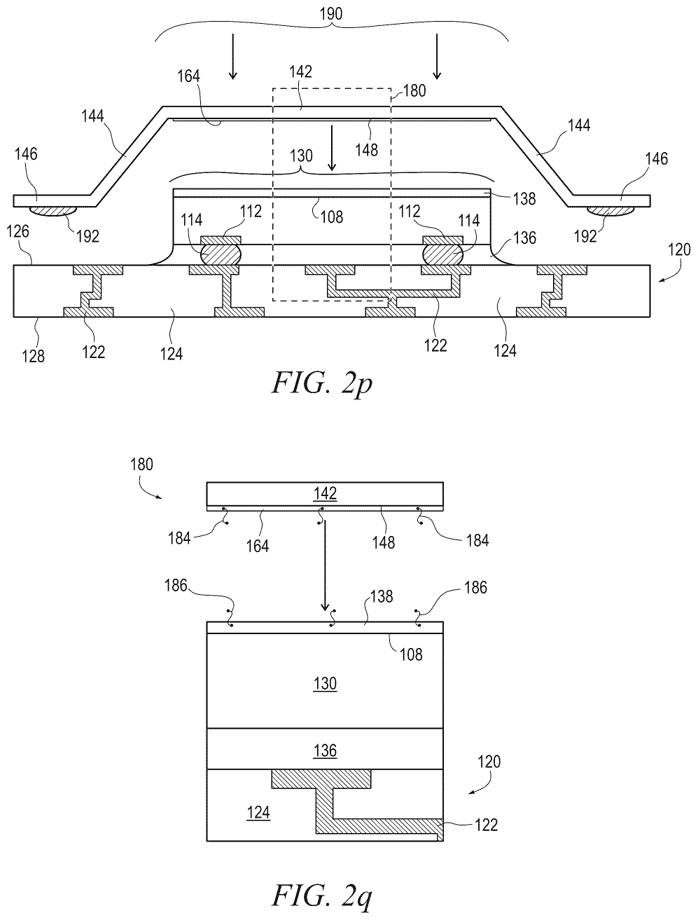

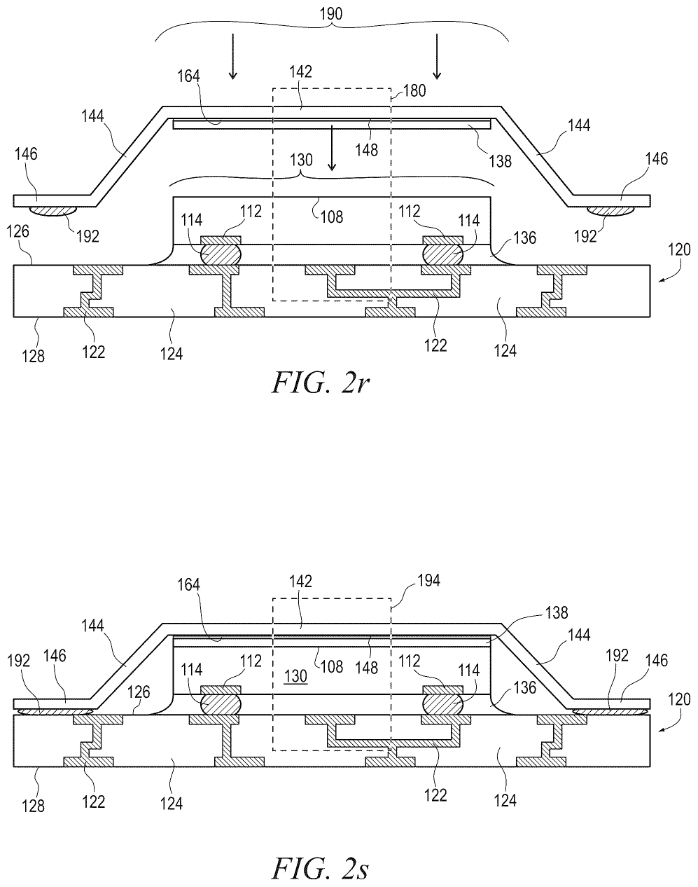

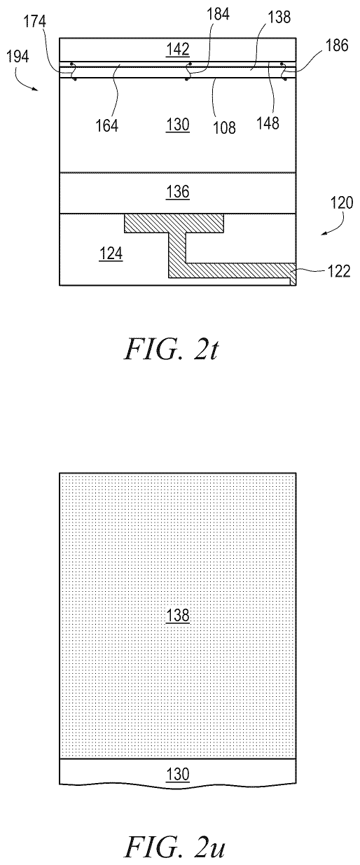

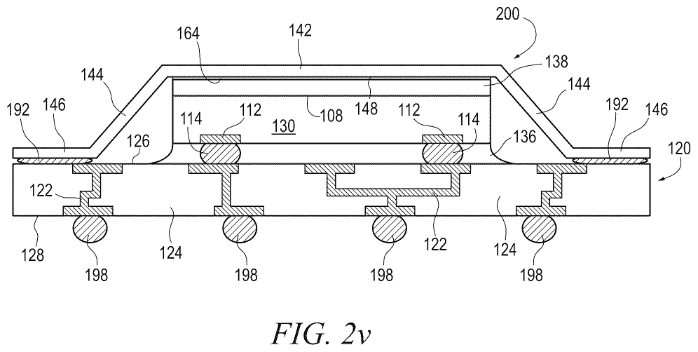

FIGS. 2a-2v illustrate a process of forming a fcBGA-H package with a plasma-enhanced surface on the head spreader to interface with the TIM. FIG. 2a shows a cross-sectional view of interconnect substrate or interposer 120 including one or more conductive layers 122 and one or more insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating process, or other suitable metal deposition process. Conductive layers 122 provide horizontal electrical interconnect across substrate 120 and vertical electrical interconnect between top surface 126 and bottom surface 128 of substrate 120. Portions of conductive layers 122 can be electrically common or electrically isolated depending on the design and function of semiconductor die 104 and other electrical components. Insulating layers 124 contain one or more layers of silicon dioxide (SiO₂), silicon nitride (Si₃N₄), silicon oxynitride (SiON), tantalum pentoxide (Ta₂O₅), aluminum oxide (Al₂O₃), solder resist, polyimide, benzocyclobutene (BCB), polybenzoxazoles (PBO), and other material having similar insulating and structural properties. Insulating layers 124 can be formed using PVD, CVD, printing, lamination, spin coating, spray coating, sintering or thermal oxidation. Insulating layers 124 provide isolation between conductive layers 122. There can be multiple conductive layers like 122 separated by insulating layers 124.

In FIG. 2b, one or more electrical components 130 are disposed on surface 126 of interposer 130 and electrically and mechanically connected to conductive layers 122. Electrical component(s) 130 are each positioned over interposer 120 using a pick and place operation. Electrical component 130 can be made similar to semiconductor die 104 from FIG. 1c with bumps 114 oriented toward surface 126 of interposer 120. Alternatively, electrical component 130 can include other semiconductor die, semiconductor package, surface mount device, discrete electrical device, interconnect structure, or IPD.

Electrical component 130 is brought into contact with surface 126 of interposer 120 and bonded to conductive layer 122 by reflowing bumps 114. FIG. 2c illustrates electrical component 130 electrically and mechanically connected to conductive layers 122 of interposer 120.

In FIG. 2d, underfill material 136, such as epoxy resin, is deposited between interposer 120 and electrical component 130 around bumps 114. In FIG. 2e, TIM layer 138 can be deposited on back surface 108 in a variety of patterns and shapes. For example, TIM layer 138 can be a serpentine pattern, as shown in the top view of FIG. 2f. TIM layer 138 can be concentric round patterns, as shown in the top view of FIG. 2g. TIM layer 138 can be rectangular with a central dot, as shown in the top view of FIG. 2h. TIM layer 138 can be a grid of dots, as shown in the top view of FIG. 2i. TIM layer 138 can be multiple parallel segments, as shown in the top view of FIG. 2j. TIM layer can be a star pattern extending outwardly toward the side surfaces of electrical component 130, as shown in the top view of FIG. 2k. TIM layer 138 is deposited as a soft, compliant material and cures to a hard material with high adhesion properties. In one embodiment, TIM layer 138 is a silicon-based adhesive with filler containing alumina (Al₂O₃), Al, Ag, or aluminum zinc oxide and a thermal conductivity of 1.9-11 W/m·K.

FIG. 2l shows heat spreader or heat sink 140 including a horizontal member 142, down-angled legs 144, and horizontal member 146. Horizontal member 142 has surface 148. Heat spreader 140 can be made of one or more layers of Al, Cu, Sn, Ni, Au, Ag, or other suitable thermally conductive material. In one embodiment, heat spreader 140 is Ni-plated Cu. FIG. 2m is a perspective view of heat spreader 140 with horizontal member 142, down-angled legs 144, and horizontal member 146.

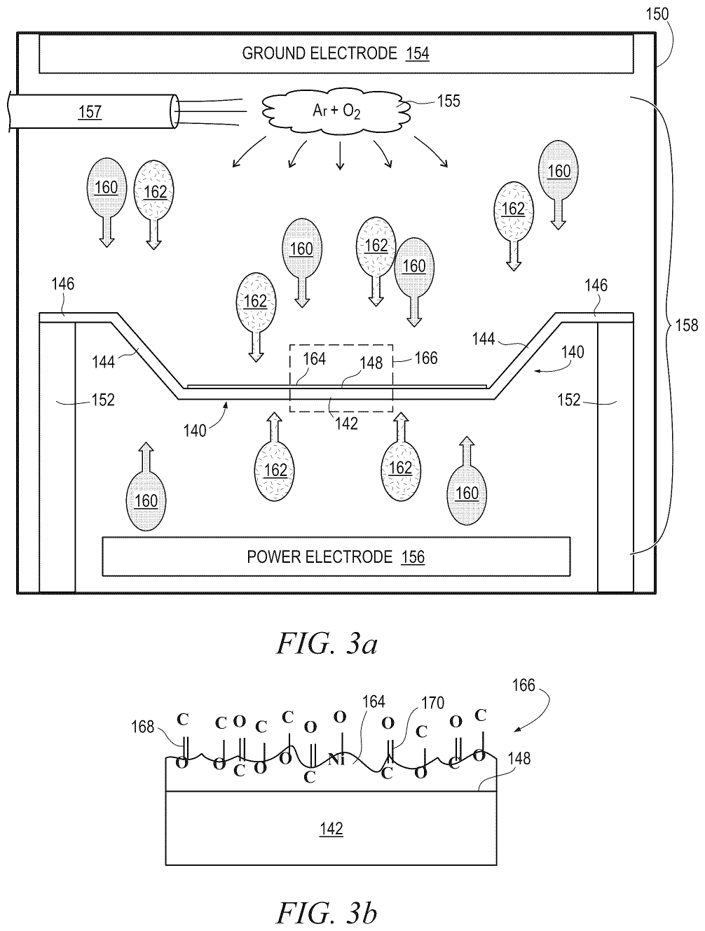

Turning to FIG. 3a, heat spreader 140 is disposed in reaction chamber 150 on pedestals 152. In one embodiment, reaction chamber 150 is a reactive ion etching (RIE) mode direct plasma chamber. Pedestals 152 extend from reaction chamber 150 to support heat spreader 140 by contacting horizontal member 146. A ground electrode 154 is disposed over surface 148 of heat spreader 140. Power electrode 156 is disposed opposite ground electrode 154. Reactant gases 155, such as argon (Ar) and oxygen (O₂), are introduced into reaction chamber 150 by way of conduit 157. As an example, reactant gases 155 can have flow rate of 10.0 standard cubic centimeters per minute (sccm) into reaction chamber 150 under 200.0 mTorr of chamber pressure for 30-60 seconds. Power electrode 156 is radio frequency (RF) signal energized to create an electric field 158 within reaction chamber 150. In one embodiment, power electrode 156 is RF powered to 350.0 kilowatts (kW) at 13.56 MHz to create electric field 158. Reactant gases 155 within electric field 158 ionizes the gas molecules and creates plasma ions. For example, the electric field can form Art ions 160 and O₂⁺ ions 162. The RF power provides high density energy to Ar and O₂ to discharge the gases and form plasma ions. The plasma ions deposit on surface 148 of heat spreader 150 and forms plasma-enhanced surface 164. In particular, Art ions 160 makes surface 148 rougher, while O₂⁺ ions 162 activates surface 148 with chemical bonding groups, leaving plasma-enhanced surface 164 with the properties of roughness and activation. Plasma-enhanced surface 164 exhibits improved tacky-ness and coverage properties.

FIG. 3b shows further detail of box 166 from FIG. 3a with a portion of plasma-enhanced surface 164 as formed on horizontal member 142 of heat spreader 140. Plasma-enhanced surface 164 has carbon (C)-oxygen (O) bonds 168 and O—C bonds 170 for the tacky-ness property.

FIG. 2n shows heat spreader 140 with plasma-enhanced surface 164, outside reaction chamber 150 post plasma treatment. FIG. 2o shows a perspective view of heat spreader 140 with plasma-enhanced surface 164, post plasma treatment.

In FIG. 2p, heat spreader 140 with plasma-enhanced surface 164 is disposed over TIM 138 and interposer 120. In one embodiment, surface 164 is plasma-enhanced Ni-plated Cu. FIG. 2q shows further detail of box 180 with plasma-enhanced surface 164 exhibiting bonding groups 184 and TIM 138 exhibiting bonding groups 186 for improved tacky-ness or adhesive properties.

In another embodiment, TIM 138 is deposited over plasma-enhanced surface 164 prior to mounting heat spreader 140 to electrical component 130, as shown in FIG. 2r.

In FIG. 2s, plasma-enhanced surface 164 of heat spreader 140 is brought into contact with TIM 138 under heat and pressure 190. Thermal paste 192 makes connection between horizontal member 146 and surface 126 of interposer 120. FIG. 2t shows further detail of box 194 with plasma-enhanced surface 164 contacting TIM 138 and bonding groups 184 and bonding groups 186 enhancing the bond. TIM 138 is cured for 30-120 minutes at 120-150° C. to form a solid bond between heat spreader 140 and electrical component 130 with exceptional TIM coverage over surface 108. FIG. 2u shows uniform and continuous TIM 138 coverage over surface 108 of electrical component 130.

In FIG. 2v, an electrically conductive bump material is deposited over conductive layer 112 on surface 128 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 198. In one embodiment, bump 198 is formed over a UBM having a wetting layer, barrier layer, and adhesive layer. Bump 198 can also be compression bonded or thermocompression bonded to conductive layer 112. Bump 198 represents one type of interconnect structure that can be formed over conductive layer 112. The interconnect structure can also use bond wires, conductive paste, stud bump, micro bump, or other electrical interconnect.

Electrical component 130 with interposer 120 and heat spreader 140 are shown as fcBGA-H package 200. Heat spreader 140 with plasma-enhanced surface 164 provides uniform and continuous TIM coverage between electrical component 130 and horizontal member 142. Physical treatment by Art ions 160 in the plasma cleans surface 148 of heat spreader 140. O₂⁺ ions 162 in the plasma provides more tacky-ness, bond-ability, or adhesive properties with TIM 138. Surface activation by O₂⁺ ions 162 provides more and stronger chemical bonding between TIM 138 and heat spreader 140. TIM 138 can endure more thermal or physical stress by chemical treatment of O₂⁺ ions in plasma. Plasma-enhanced surface 164 with TIM 138 reduces risk of delamination.

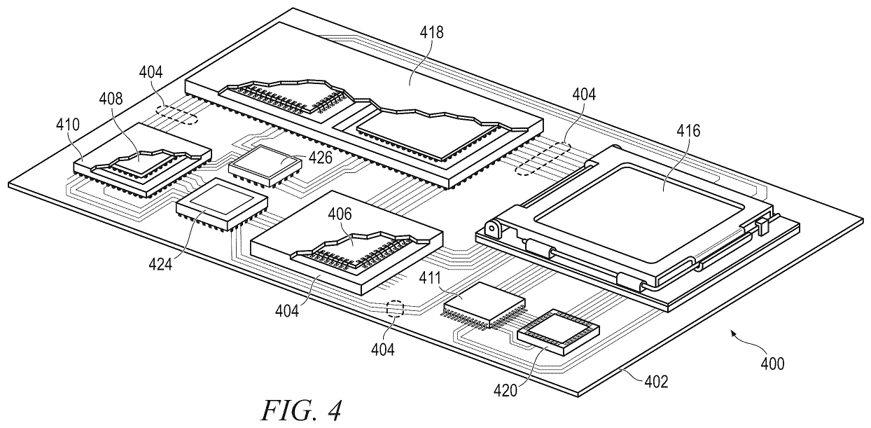

FIG. 4 illustrates electrical device 400 having a chip carrier substrate or PCB 402 with a plurality of semiconductor packages disposed on a surface of PCB 402, including fcBGA-H package 200. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 4, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
an electrical component disposed over the substrate;
a heat spreader including a plasma-enhanced surface disposed over the electrical component; and
a thermal interface material (TIM) disposed between the electrical component and plasma-enhanced surface of the heat spreader.

2. The semiconductor device of claim 1, wherein the plasma-enhanced surface includes argon ions and oxygen ions.

3. The semiconductor device of claim 1, wherein the plasma-enhanced surface includes properties of roughness and tacky-ness.

4. The semiconductor device of claim 1, wherein the plasma-enhanced surface includes a chemical bonding group.

5. The semiconductor device of claim 1, further including an underfill material deposited between the electrical component and substrate.

6. The semiconductor device of claim 1, wherein the electrical component includes a flipchip type semiconductor die.

7. A semiconductor device, comprising:
an electrical component;
a heat spreader including a plasma-enhanced surface disposed over the electrical component; and
a thermal interface material (TIM) disposed between the electrical component and plasma-enhanced surface.

8. The semiconductor device of claim 7, further including a substrate, wherein the electrical component is disposed over the substrate.

9. The semiconductor device of claim 7, wherein the plasma-enhanced surface includes argon ions and oxygen ions.

10. The semiconductor device of claim 7, wherein the plasma-enhanced surface includes properties of roughness and tacky-ness.

11. The semiconductor device of claim 7, wherein the plasma-enhanced surface includes a chemical bonding group.

12. The semiconductor device of claim 7, further including an underfill material deposited between the electrical component and substrate.

13. The semiconductor device of claim 7, wherein the electrical component includes a flipchip type semiconductor die.

14. A method of making a semiconductor device, comprising:
providing a substrate;
disposing an electrical component over the substrate;
disposing a heat spreader including a plasma-enhanced surface over the electrical component; and
disposing a thermal interface material (TIM) between the electrical component and plasma-enhanced surface of the heat spreader.

15. The method of claim 14, further including:
disposing the heat spreader in a reaction chamber;
introducing argon and oxygen into the reaction chamber; and
forming an electric field within the reaction chamber to ionize the argon and oxygen and form the plasma-enhanced surface.

16. The method of claim 14, wherein the plasma-enhanced surface includes properties of roughness and tacky-ness.

17. The method of claim 14, wherein the plasma-enhanced surface includes a chemical bonding group.

18. The method of claim 14, further including depositing an underfill material between the electrical component and substrate.

19. The method of claim 14, wherein the electrical component includes a flipchip type semiconductor die.

20. A method of making a semiconductor device, comprising:
providing an electrical component;
disposing a heat spreader including a plasma-enhanced surface over the electrical component; and
disposing a thermal interface material (TIM) between the electrical component and plasma-enhanced surface.

21. The method of claim 20, further including:
providing a substrate; and
disposing the electrical component over the substrate.

22. The method of claim 20, further including:
disposing the heat spreader in a reaction chamber;
introducing argon and oxygen into the reaction chamber; and
forming an electric field within the reaction chamber to ionize the argon and oxygen and form the plasma-enhanced surface.

23. The method of claim 20, wherein the plasma-enhanced surface includes properties of roughness and tacky-ness.

24. The method of claim 20, further including depositing an underfill material between the electrical component and substrate.

25. The method of claim 20, wherein the electrical component includes a flipchip type semiconductor die.
